(19) United States
(12) Patent Application Publication
(10) Pub. No.: US 2013/0062657 A1
(43) Pub. Date: Mar. 14, 2013

(54) LIGHT EMITTING DIODE STRUCTURE AND MANUFACTURING METHOD THEREOF

(71) Applicants: Kuo-Lung Fang, Hsinchu County (TW); Jui-Yi Chu, Taichung City (TW); Jun-Rong Chen, Taichung City (TW); Chi-Wen Kuo, Tainan City (TW)

(72) Inventors: Kuo-Lung Fang, Hsinchu County (TW); Jui-Yi Chu, Taichung City (TW); Jun-Rong Chen, Taichung City (TW); Chi-Wen Kuo, Tainan City (TW)

(73) Assignee: LEXTAR ELECTRONICS CORPORATION, Hsinchu (TW)

(21) Appl. No.: 13/614,090

(22) Filed: Sep. 13, 2012

(30) Foreign Application Priority Data
Sep. 14, 2011 (TW) 100132975

(51) Int. Cl. H01L 33/62

(52) U.S. Cl. 257/99; 438/42; 438/45; 257/E33.062

(57) ABSTRACT

A light-emitting diode structure is disclosed. A substrate has a first semiconductor layer, a light-emitting layer and a second semiconductor layer formed thereon. The first and second semiconductor layers are of opposite conductivity types. A first contact electrode is disposed between the first semiconductor layer and the substrate, and has a protruding portion extending into the second semiconductor layer. A barrier layer is conformally formed on the first contact electrode and exposes a top surface of the protruding portion. A current blocking member is disposed on the barrier layer and around at least a sidewall of the protruding portion. A second contact electrode is disposed between the first semiconductor layer and the first contact electrode, and in direct contact with the first semiconductor layer, wherein the second contact electrode is electrically insulated from the first contact electrode by the barrier layer.

### RELATED APPLICATIONS

This application claims priority to Taiwan Application Serial Number 100132975, filed Sep. 14, 2011, which is herein incorporated by reference.

### BACKGROUND

1. Field of Invention

The present invention relates to a light-emitting diode structure. More particularly, the present invention relates to a light-emitting diode structure and manufacturing method thereof for improving the current crowding problem.

2. Description of Related Art

Light emitting diodes (LED) are equipped with several advantages, such as high brightness, small size, light weight, not easy to damage, low power consumption and long lifetime such that it is widely used in all kinds of display products. The emitting principle of LED is to form a two diode forward bias, and the majority electron holes in the p-type region will move to the n-type region while the majority electrons move to the p-type region, and finally the two carriers meet in the depletion layer of a p-n-junction. Because the electrons from the conduction band migrate to the valence band and release energy by means of photon mode, thereby generating light.

In the traditional horizontal LED device, the contact electrode is designed in a horizontal direction, which is prone to the problem of current crowding. For example, the electrons in the n-type epitaxial layer and p-type epitaxial layer horizontally move unequally, resulting in the LED luminous uneven. In addition, the contact electrode of the LED is designed to cover the light-emitting surface, thereby reducing the light-emitting area, and only about 65% of the light-emitting area can be used.

The general n-type contact electrodes of the vertical LED structure is located above the surface of the LED chip. In general, the more metal contact electrodes are set on the surface of the LED chip, the LED chip current distribution can be more uniform. However, the metal contact electrodes set in a top surface of the vertical LED structure have the surface absorptivity issues or blocking the light extraction issues. Furthermore, as the electrons and electron holes will attract each other, and in the current crowding occurs near the n-type contact electrode, resulting in uneven luminescence of the LED chip.

For the forgoing reasons, there is a need for an innovative light-emitting diode structure and manufacturing method thereof.

### SUMMARY

An embodiment of this invention provides a light-emitting diode structure, which includes: a substrate having a first semiconductor layer, a light-emitting layer and a second semiconductor layer formed thereon, wherein the light-emitting layer and the first semiconductor layer are sequentially disposed on the second semiconductor layer, and the first and second semiconductor layers are of opposite conductivity types; a first contact electrode disposed between the first semiconductor layer and the substrate, and having a protruding portion extending into the second semiconductor layer; a barrier layer conformally formed on the first contact electrode and expose a top surface of the protruding portion; a current blocking member disposed on the barrier layer and around at least a sidewall of the protruding portion; and a second contact electrode disposed between the first semiconductor layer and the first contact electrode, and in direct contact with the first semiconductor layer, wherein the second contact electrode is electrically insulated from the first contact electrode by the barrier layer.

Another embodiments of this invention provides a manufacturing method for a light-emitting diode structure, which includes: providing a first substrate having a first semiconductor layer formed thereon; forming a first opening on the first semiconductor layer; forming a lump member within the first opening; sequentially forming a light-emitting layer and a second semiconductor layer on the first semiconductor layer, wherein the first and second semiconductor layers are of opposite conductivity types; forming a current blocking member, wherein forming the current blocking member comprises removing at least a portion of the lump member to form a second opening which exposes the first semiconductor layer, and wherein the second opening is surrounded by the current blocking member; forming a first contact electrode on an upper surface of the second semiconductor layer; conformally forming a barrier layer over the first contact electrode and the second opening; forming a second contact electrode over the first contact electrode and the second opening; and forming a second substrate over the second contact electrode and removing the first substrate.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1A-1P illustrate diagrammatic sectional views of manufacturing an LED structure in a number of successive stages according to one embodiment of this invention;

FIGS. 2A-2D illustrate diagrammatic sectional views of manufacturing an LED structure according to another embodiment of this invention; and

FIGS. 3A-3C illustrate diagrammatic sectional views of manufacturing an LED structure according to still another embodiment of this invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts. It should be understood that, although the terms “first,” “second,” etc. may be used herein to describe various elements, these terms should not be construed as being limiting (e.g., describing a particular order or number of elements), but rather, as being merely descriptive, i.e., labels that distinguish one element from another, as is commonly used within the field of patent law. Thus, for example, although one embodiment of the invention may be described as having a “first” element present and a “second” element present, other embodiments of the invention may have a “first” element present but no “second” element present, a “second” element present but no “first” element present, two (or more) “first” elements present, and/or two (or more) “second” elements present, etc., and/or additional elements such as a “first” element, a “second” element, and a “third” element, without departing from the scope of the present invention.

The present invention provides an LED structure of high luminous efficiency and manufacturing method thereof. This LED structure can effectively improve the current crowding and prevent the contact electrode from the surface absorptivity issues or blocking the light extraction issues.

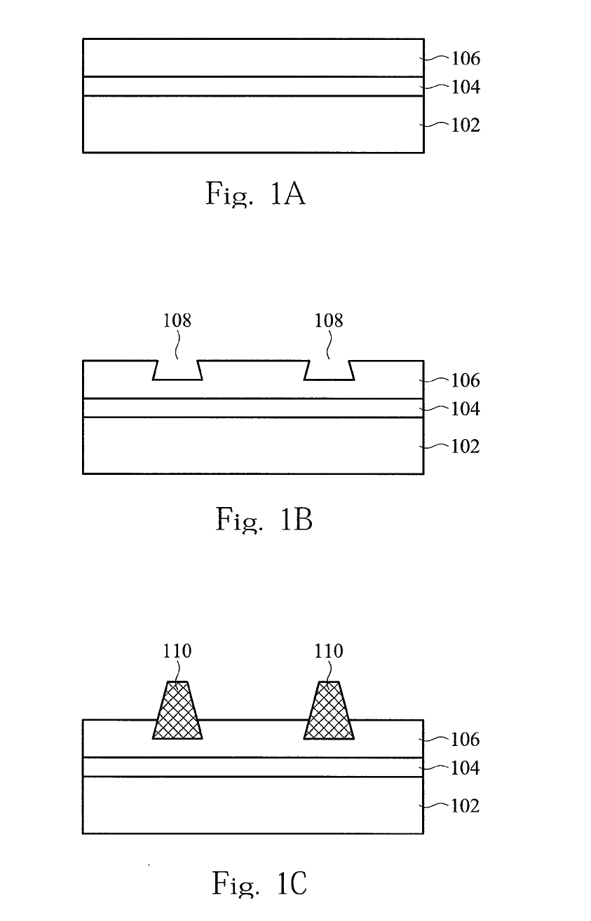

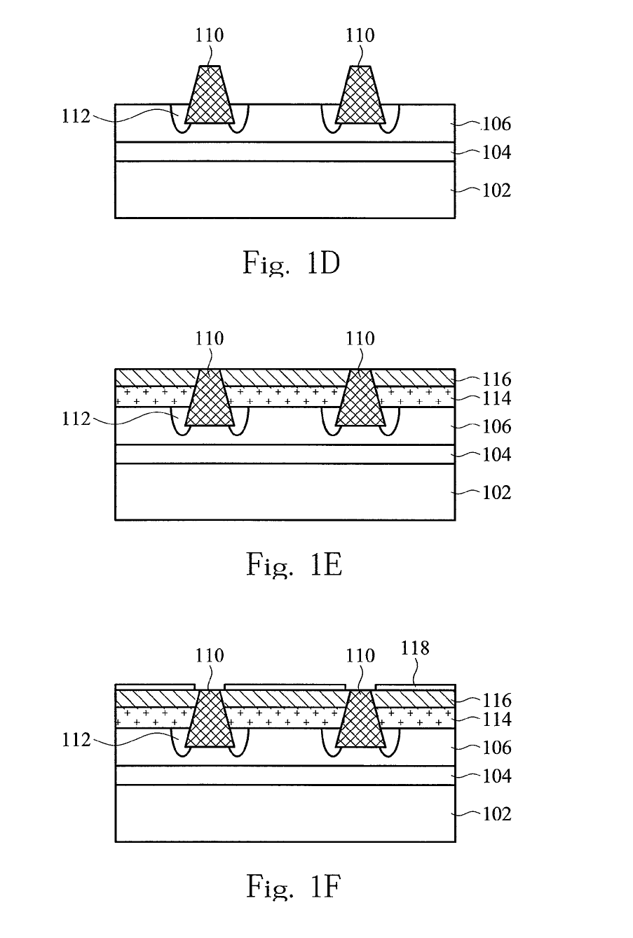

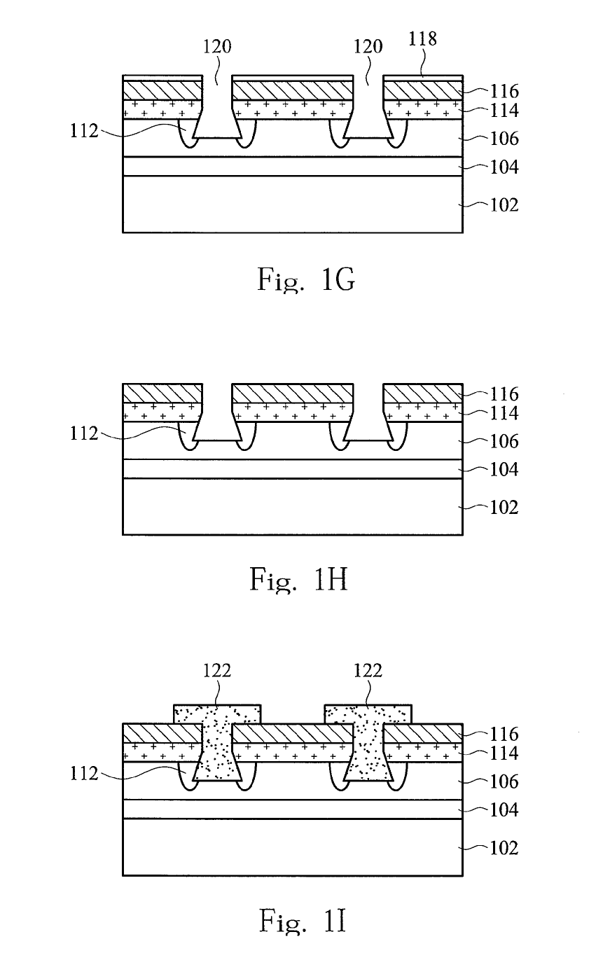

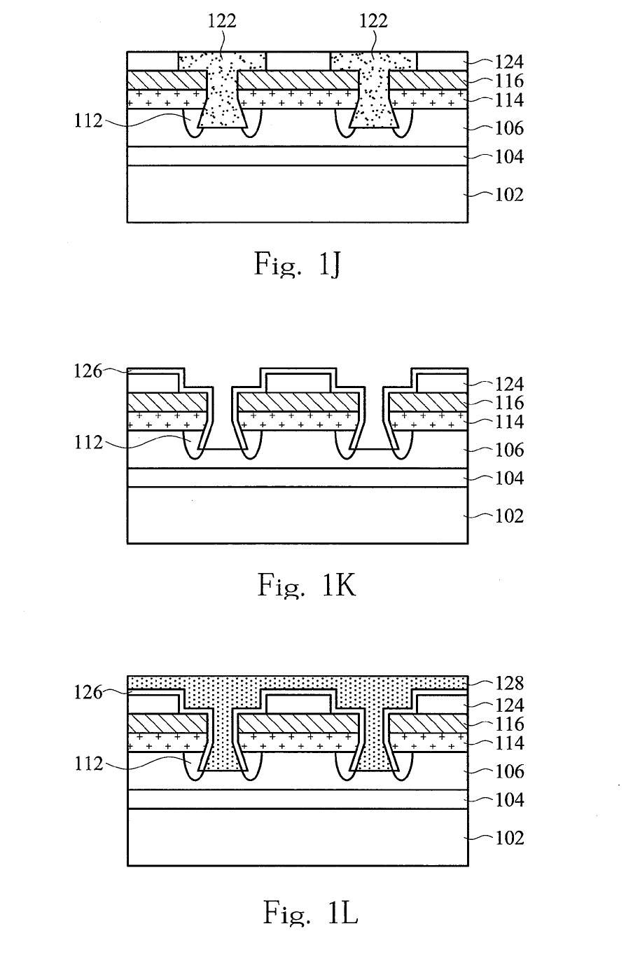

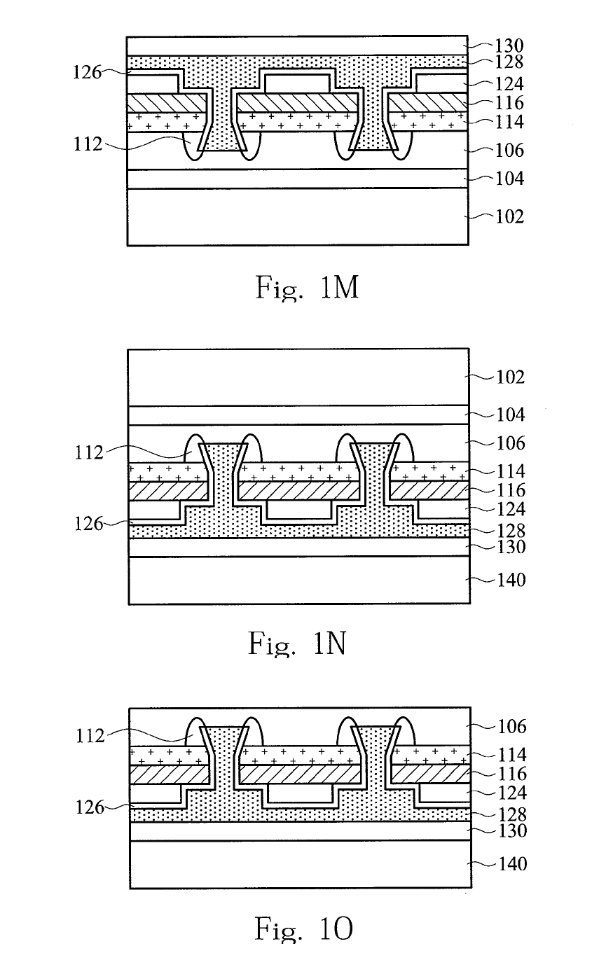

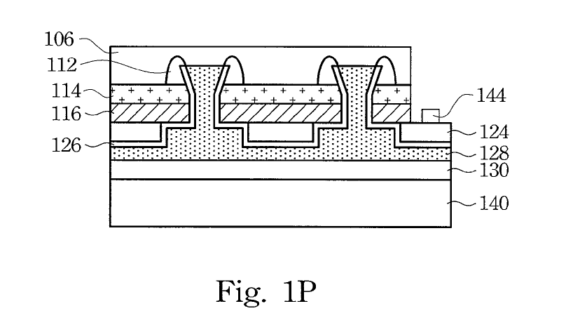

FIGS. 1A-1P illustrate diagrammatic sectional views of manufacturing an LED structure in a number of successive stages according to one embodiment of this invention.

Referring to FIG. 1A, a growth substrate 102, e.g., an aluminum oxide substrate (sapphire substrate), a silicon carbide substrate or a gallium arsenide substrate, is provided for growing a light-emitting semiconductor thereon. A buffer layer 104 and a first semiconductor layer 106 are formed on the growth substrate 102. The buffer layer 104 can be GaN, AlN, AlGaN or any combinations thereof. The buffer layer 104 provides a growth buffer for the first semiconductor layer 106 to be grown thereon and prevents the first semiconductor layer 106 from growth cracking. The first semiconductor layer 106 can be N-type epitaxial layer, e.g., GaN, AlGaN, InGaN, AlInGaN, GaP, GaAsP, GaInP, AlGaInP, AlGaAs or any combinations thereof. The buffer layer 104 and the first semiconductor layer 106 can be formed by any conventional epitaxy growth method, e.g., chemical vapor deposition (CVD), metal organic chemical vapor deposition (MOCVD), plasma enhanced chemical vapor deposition (PECVD), molecular beam epitaxy, hydride vapor phase epitaxy or sputtering. In an embodiment, the first semiconductor layer 106 has a thickness ranging from about 0.1 μm to about 5.0 μm.

Referring to FIG. 1B, at least an opening 108 is formed on the first semiconductor layer 106. In an embodiment, the opening 108 can be a square, triangle, circle, ellipse, polygon or any other shapes of a radius ranging from about 50 μm to about 150 μm.

Referring to FIG. 1C, a lump member 110 is formed within the opening 108. In an embodiment, the lump member 110 may protrude out of the first semiconductor layer 106 or a top surface of the lump member 110 may even be higher than or aligned with a top surface of a second semiconductor layer 116 that is formed on the first semiconductor layer 106 (Referring to FIG. 1E). In this embodiment, the lump member 110 can have a height ranging from about 1.0 μm to about 10.0 μm. In another embodiment, a top surface of the lump member 110 may be lower than a top surface of the first semiconductor layer 106 (not illustrated in the drawings). The lump member 110 can be formed by a deposition process, e.g., chemical vapor deposition, physical vapor deposition, other vapor deposition or sputtering, and followed by a photolithography and etching process. The lump member 110 can be any high resistance materials, e.g., silicon oxide, silicon nitride, zinc oxide or any combinations thereof. The lump member 110 can be a trapezoidal cylinder, square cylinder, circular cylinder, corner tapered cylinder or any other three-dimensional shape.

Referring to FIG. 1D, an implanting process is executed using the lump member 110 as a mask to dope the first semiconductor layer 106 so as to form a current blocking member 112. A portion of the first semiconductor layer 106 may be doped with silicon and magnesium dopant to form a high resistance section, and the implanting process can be an ion bombardment method. In addition to silicon and magnesium, argon or oxygen may be doped into the first semiconductor layer 106 to form the current blocking member 112.

Referring to FIG. 1E, a light-emitting layer 114 and a second semiconductor layer 116 are sequentially formed on the first semiconductor layer 106. The light-emitting layer 114 can be a semiconductor light-emitting layer equipped with multiple quantum well (MQW) structure. The light-emitting layer 114 can be selected from chemical elements of III-V family, chemical elements of the II-VI group, chemical elements of IV family or chemical elements of IV-IV family. The second semiconductor layer 116 and the first semiconductor layer 106 can be of opposite conductivity types, e.g., the second semiconductor layer 116 can be p-type epitaxial layer while the first semiconductor layer 106 can be n-type epitaxial layer. The second semiconductor layer 116 can also be selected from chemical elements of III-V family, chemical elements of the II-VI group, chemical elements of IV family, chemical elements of IV-IV family or any combinations thereof, e.g., GaN, AlGaN, InGaN, AlInGaN, GaP, GaAsP, GaInP, AlGaInP, AlGaAs or any combination thereof. The light-emitting layer 114 and the second semiconductor layer 116 be formed by any conventional epitaxy growth method, e.g., chemical vapor deposition (CVD), metal organic chemical vapor deposition (MOCVD), plasma enhanced chemical vapor deposition (PECVD), molecular beam epitaxy, hydride vapor phase epitaxy or sputtering. The second semiconductor layer 116 has a thickness ranging from about 0.1 μm to about 5.0 μm. It is noted that the second semiconductor layer and the first semiconductor layer may have their conductivity types exchanged in different embodiments, e.g., in an embodiment, the first semiconductor layer 106 is of n-type epitaxial layer while the second semiconductor layer 116 is of p-type epitaxial layer; in another embodiment, the first semiconductor layer 106 is of p-type epitaxial layer while the second semiconductor layer 116 is of n-type epitaxial layer.

In the embodiment that the lump member 110 protrude our of the first semiconductor layer 106, a top surface of the second semiconductor layer 116 may be grown to be higher than or aligned with a top surface of the lump member 110. When the top surface of the second semiconductor layer 116 is higher than the top surface of the lump member 110, the second semiconductor layer 116 may be polished by chemical mechanical planarization to achieve a desired thickness and expose the top surface of the lump member 110.

In the embodiment that the top surface of the lump member 110 is lower than the top surface of the first semiconductor layer 106, because depositing crystalline on the lump member 110 is slower than depositing crystalline on the first semiconductor layer 106, after the light-emitting layer 114 and the second semiconductor layer 116 are formed, there is only a very thin and bad-quality epitaxy layer formed on the lump member 110 or even the lump member 110 may not be fully covered by the epitaxy layer and exposed. Therefore, the very thin and bad-quality epitaxy layer does not affect an etching process to remove the lump member 110, namely, the very thin and bad-quality epitaxy layer can be entirely removed by the same etching process.

It is noted that in an embodiment of FIG. 1C, the implanting process may be executed after the light-emitting layer 114 and the second semiconductor layer 116 are formed. In this embodiment, the implanting process can be executed only upon the first semiconductor layer 106; or upon the first semiconductor layer 106 and the light-emitting layer 114; or upon the first semiconductor layer 106, the light-emitting layer 114 and the second semiconductor layer 116; or only upon the second semiconductor layer 116. Therefore, in addition to the current blocking member 112 illustrated in FIG. 1D, which is formed only in the first semiconductor layer 106, the current blocking member can be formed in both the first semiconductor layer 106 and the light-emitting layer 114 (not illustrated in the drawings); or formed in all the first semiconductor layer 106, the light-emitting layer 114 and second semiconductor layer 116 (not illustrated in the drawings); or formed only in second semiconductor layer 116 (not illustrated in the drawings).

Referring to FIG. 1F, a patterned photoresist layer 118 is formed on the second semiconductor layer 116. The patterned photoresist layer 118 fully covers the second semiconductor layer 116 and exposes the lump member 110 only. Next, referring to FIG. 1G, an etching process is used to remove the lump member 110 and form an opening 120. Thus, the opening 120 has a shape corresponding to the removed lump member 110. The etching process can be a dry etching process or a wet dry etching process. In an embodiment, because the wet dry etching process tends to create an undercut upon the second semiconductor layer 116 when the lump member 110 is being removed, the opening 120 can be expanded in its upper portion and beneficial for depositing the barrier layer 126 and the contact electrode 128 into the opening 120 with less bubbles or defects. Next, referring to FIG. 1H, the patterned photoresist layer 118 is removed.

Next, referring to FIG. 1I, an filler material 122 is formed into the opening 120 and protrudes out of the second semiconductor layer 116. In an embodiment, the filler material 122 and the lump member 110 can be formed by the same or similar materials and processes. A top surface of the filler material 122 can be higher than a top surface of the second semiconductor layer 116 by a distance ranging from about 0.001 μm to about 0.5 μm, which results in a thickness of the contact electrode 124 formed in next step.

Referring to FIG. 1J, the contact electrode 124 is formed in the second semiconductor layer 116. The contact electrode 124 can be ohmic contact materials (e.g., palladium, platinum, nickel, gold, silver or any combinations thereof), transparent conductive materials (e.g., nickel oxide, indium tin oxide, cadmium tin oxide, antimony tin oxide, zinc aluminum, or zinc oxide tin), a reflective layer or any combinations thereof. For example, the contact electrode 124 can be a combination of ohmic contact materials and the reflective layer, which reflects the light from the light-emitting layer 114 to enhance the light extraction efficiency. In an embodiment, the contact electrode 124 may include an additional insulation layer (not illustrated in the drawings), and the insulation layer can be silicon nitride, silicon oxide, other dielectric materials or any combinations thereof. In another embodiment, the contact electrode 124 may be at least 5 μm, e.g., 5 μm-20 μm, horizontally distant from a top portion of the opening 120 and preferably be about 10 μm. That is, the contact electrode 124 shrinks at least 5 μm from the opening 120, thereby reducing the possibilities that electrons and electron holes are combined near the contact electrode 124.

Next, referring to FIG. 1K, the barrier layer 126 is conformally formed over sidewalls of the openings 120, and upper surfaces of the contact electrode 124 and the second semiconductor layer 116. The barrier layer 126 can be silicon nitride, silicon oxide, other dielectric materials or any combinations thereof. The barrier layer 126 has a thickness ranging from about 0.01 μm to about 0.5 μm. The barrier layer 126 is conformally formed over inner sidewalls and bottom walls of the openings 120 by chemical vapor deposition, physical vapor deposition or other deposition methods, and followed by a photolithography and etching process to remove a portion of the barrier layer over bottom walls of the openings 120.

Next, referring to FIG. 1L, the contact electrode 128 is formed into opening 120. In an embodiment, the contact electrode 128 fully covers the contact electrode 124 and the second semiconductor layer 116. The contact electrode 128 includes a protruding portion extending into the opening 120 and a horizontal portion covering the second semiconductor layer 116 and the contact electrode 124. The protruding portion of the contact electrode 128 is electrically insulated from the second semiconductor layer 116 and the light-emitting layer 114 by the barrier layer 126, and in direct contact with the first semiconductor layer 106 through a bottom portion of the opening 120. The horizontal portion of the contact electrode 128 is electrically insulated from the contact electrode 124 by the barrier layer 126. The contact electrode 128 can be ohmic contact materials (e.g., palladium, platinum, nickel, gold, silver or any combinations thereof), transparent conductive materials (e.g., nickel oxide, indium tin oxide, cadmium tin oxide, antimony tin oxide, zinc aluminum, or zinc oxide tin), or combination thereof.

Next, referring to FIG. 1M, a metal adhesive layer 130 is formed on the contact electrode 128. The metal adhesive layer 130 may include Au, Sn, In, any alloys thereof or any combinations thereof. The metal adhesive layer 130 has a thickness ranging from about 0.5 μm to about 10 μm. Next, referring to FIG. 1N, a support substrate 140 is bonded to the metal adhesive layer 130. The support substrate 140 can be a package substrate equipped with electric circuits such that the contact electrode 128 can be electrically connected with an outer circuit via the package substrate.

Next, Referring to FIG. 1O, the growth substrate 102 is removed. In an embodiment, a laser lift-off process is used to remove the growth substrate 102. In another embodiment, a wet etching process is used to remove the growth substrate 102. The buffer layer 104 may be removed with the growth substrate 102 by the same process.

Finally, referring to FIG. 1P, a lateral portion of the LED structure is etched to remove a part of the first semiconductor layer 106, the light-emitting layer 114 and the second semiconductor layer 116 to form a cutout, which exposes part of the contact electrode 124. A bonding pad 144 is formed on the exposed portion of the contact electrode 124 to achieve a final LED structure according to an embodiment of this invention.

In this LED structure, the second semiconductor layer 116, the light-emitting layer 114 and the first semiconductor layer 106 are sequentially arranged on the support substrate 140. The contact electrode 128 includes a protruding portion extending into first semiconductor layer 106 and a horizontal portion located between the second semiconductor layer 116 and the support substrate 140. The barrier layer 126 is conformally formed on the contact electrode 124, but exposes a top surface of the contact electrode 128. The current blocking member 112 is located on the barrier layer 126 and around at least a sidewall of the protruding portion of the contact electrode 128 so as to stop vertical electrical currents near the contact electrode 128 and allow more horizontal electrical currents, thereby reducing electrical current density around the contact electrode 128. The contact electrode 124 is located between the contact electrode 128 and the second semiconductor layer 116, and in direct contact with the second semiconductor layer 116. The contact electrode 124 is electrically insulated from the contact electrode 128 by the barrier layer 126. The contact electrode 124 is electrically with an outer circuit via the bonding pad 144, and the contact electrode 128 is electrically with the outer circuit via the metal adhesive layer 130 and circuits on the support substrate 140.

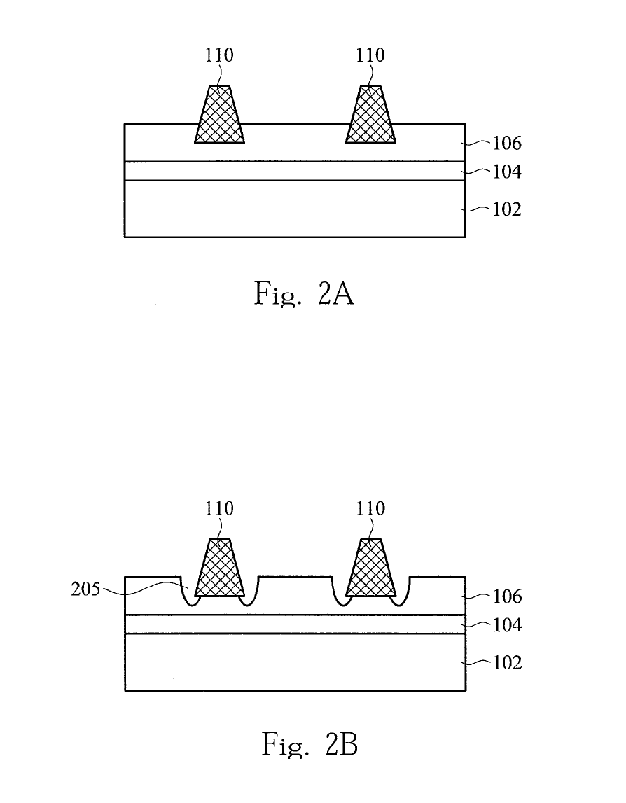

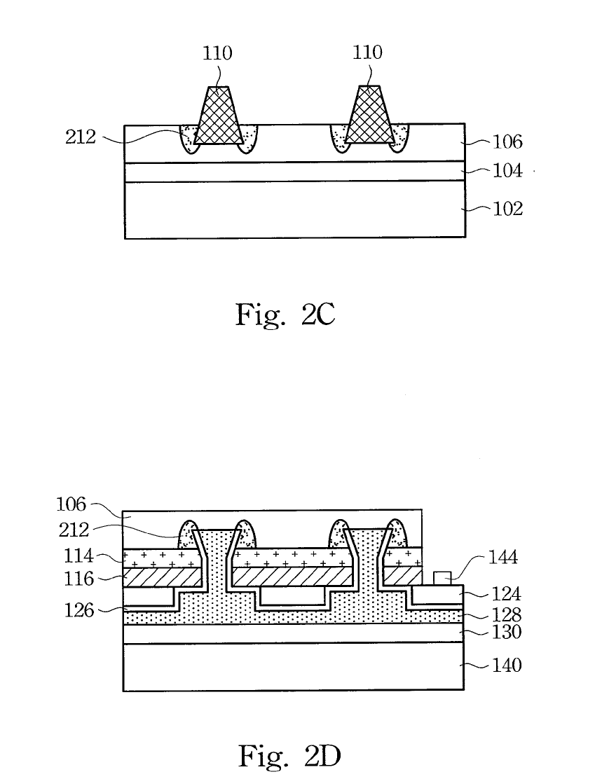

FIGS. 2A-2D illustrate diagrammatic sectional views of manufacturing an LED structure according to another embodiment of this invention. In this embodiment, the elements labeled with the same reference numerals as the elements in FIGS. 1A-1P are formed by the same or similar materials.

Referring to FIG. 2A first, the LED structure in this figure is similar to the LED structure in FIG. 1C, which is formed by the same steps illustrated FIGS. 1A-1C, the growth substrate 102 has the buffer layer 104 and the first semiconductor layer 106 formed thereon. The first semiconductor layer 106 has the lump member 110, which protrudes out of the first semiconductor layer 106 or has its top surface under the top surface of the first semiconductor layer 106. This embodiment (FIGS. 2A-2D) is different from the previous embodiment (FIGS. 1A-1P) in that no implanting process is used to form the current blocking member. Instead, a photolithography and etching process is executed using the lump member 110 as a mask to remove a portion around the lump member 110 to form an opening 205 (referring to FIG. 2B), which is used to form the current blocking member 212.

Next, referring to FIG. 2C, the current blocking member 212 is formed within the opening 205 by a deposition process (such as chemical vapor deposition, physical vapor deposition, vapor deposition, sputtering), and followed by a photolithography and etching process. The current blocking member 212 can be oxide materials with high resistance, e.g., silicon oxide, silicon nitride, zinc oxide, or any combinations thereof The current blocking member 212 can be a trapezoidal cylinder, square cylinder, circular cylinder, corner tapered cylinder or any other three-dimensional shape.

Next, referring to FIG. 2D, the LED structure in this figure is formed by the same steps illustrated FIGS. 1E and 1P. In this LED structure, the current blocking member 212 in this embodiment (FIGS. 2A-2D) is formed in the same location as the previous embodiment (FIGS. 1A-1P), but is formed by different materials and processes. Furthermore, the current blocking member 212 is formed only in first semiconductor layer 106.

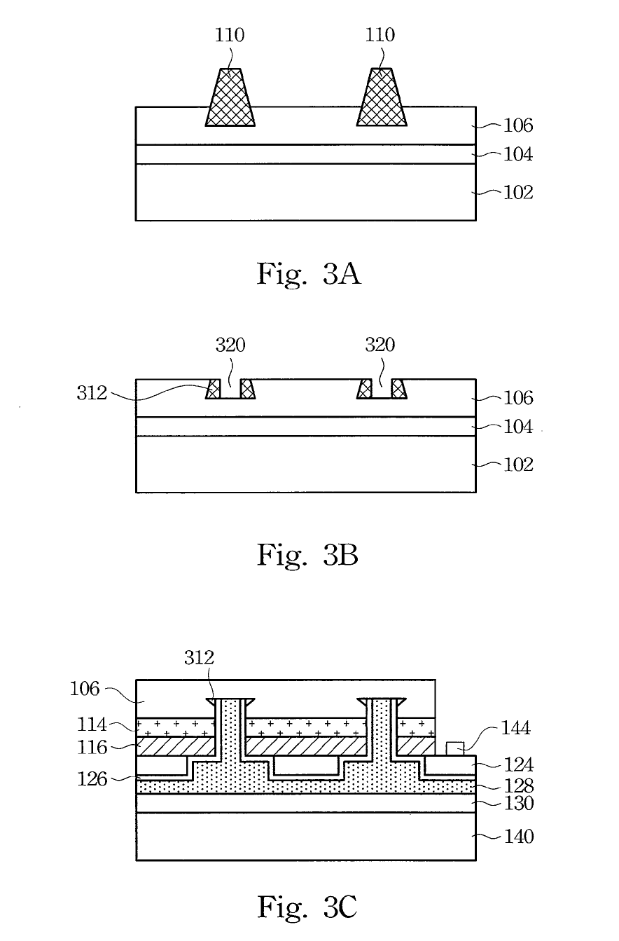

FIGS. 3A-3C illustrate diagrammatic sectional views of manufacturing an LED structure according to still another embodiment of this invention. In this embodiment, the elements labeled with the same reference numerals as the elements in FIGS. 1A-1P are formed by the same or similar materials.

Referring to FIG. 3A first, the LED structure in this figure is similar to the LED structure in FIG. 1C, which is formed by the same steps illustrated FIGS. 1A-1C, the growth substrate 102 has the buffer layer 104 and the first semiconductor layer 106 formed thereon. The first semiconductor layer 106 has the lump member 110, which protrudes out of the first semiconductor layer 106 or has its top surface under the top surface of the first semiconductor layer 106. This embodiment (FIGS. 3A-3C) is different from the previous embodiment (FIGS. 1A-1P) in that no implanting process is used to form the current blocking member. Instead, a nonisotropic etching process is executed to remove a central portion of the lump member 110 to form an opening 320 (referring to FIG. 3B), of which the remaining lump member is used to form the current blocking member 312. Referring to FIG. 3B, the opening 320 is surrounded by the remaining lump member, i.e., the current blocking member 312, which exposes the first semiconductor layer 106. The lump member 110 can be high resistance materials, e.g., silicon oxide, silicon nitride, zinc oxide, or any combinations thereof.

Next, the light-emitting layer 114 and the second semiconductor layer 116 are formed on the first semiconductor layer 106, and followed by the same steps illustrated FIGS. 1E and 1P to form the complete LED structure in FIG. 3C. It is noted that in another embodiment, the step of removing a central portion of the lump member 110 can also be executed after the light-emitting layer 114 and/or the second semiconductor layer 116 are formed and executed by using the nonisotropic etching process as used in the previous embodiment (FIG. 3B). The current blocking member can be adjusted in its size and shape by different etching recipes. For example, the current blocking member 312 can be a trapezoidal cylinder, square cylinder, circular cylinder, corner tapered cylinder or any other three-dimensional shape, and formed only in first semiconductor layer 106; or formed in both the first semiconductor layer 106 and the light-emitting layer 114 (not illustrated in the drawings); or formed in all the first semiconductor layer 106, the light-emitting layer 114 and the second semiconductor layer 116 (not illustrated in the drawings).

In this LED structure, the current blocking member 312 in this embodiment (FIGS. 3A-3C) is formed in the same location as the current blocking member 112 in the previous embodiment (FIGS. 1A-1P), but is formed by different materials and processes. Furthermore, the current blocking member 312 is formed only in first semiconductor layer 106; or formed in both the first semiconductor layer 106 and the light-emitting layer 114 (not illustrated in the drawings); or formed in all the first semiconductor layer 106, the light-emitting layer 114 and the second semiconductor layer 116 (not illustrated in the drawings). In addition, it is noted that the filler material 122 in this embodiment is preferably selected from the materials with an etching selectivity ratio different from the current blocking member 312 has. Therefore, when the filler material 122 is being etched, the current blocking member 312 is not etched due to the different etching selectivity ratio.

According the above-discussed embodiments, the LED structure herein is equipped the current blocking member (112, 212, 312) of high resistance at an interface between the contact electrode 128 and the first semiconductor layer 106, thereby stopping vertical electrical currents and allowing more horizontal electrical currents, thereby reducing electrical current density around the contact electrode 128. Furthermore, a protruding portion of the contact electrode 128 is 5-20 μm horizontally distant from the contact electrode 124, thereby reducing the possibilities that electrons and electron holes are combined near the contact electrode 124. Moreover, the contact electrode 124 is designed within the LED structure to avoid the surface absorptivity issues or blocking the light extraction issues. In sum, the LED structure herein effectively improves the current crowding and uneven luminous problem, and improves the luminous efficiency.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light-emitting diode structure comprising:
a substrate having a first semiconductor layer, a light-emitting layer and a second semiconductor layer formed thereon, wherein the light-emitting layer and the first semiconductor layer are sequentially disposed on the second semiconductor layer, and the first and second semiconductor layers are of opposite conductivity types;
a first contact electrode disposed between the first semiconductor layer and the substrate, and having a protruding portion extending into the second semiconductor layer;
a barrier layer conformally formed on the first contact electrode and exposing a top surface of the protruding portion;
a current blocking member disposed on the barrier layer and around at least a sidewall of the protruding portion; and
a second contact electrode disposed between the first semiconductor layer and the first contact electrode, and in direct contact with the first semiconductor layer, wherein the second contact electrode is electrically insulated from the first contact electrode by the barrier layer.

2. The light-emitting diode structure of claim 1, wherein the current blocking member comprises the first semiconductor layer doped with silicon, magnesium or combination thereof.

3. The light-emitting diode structure of claim 2, wherein the current blocking member further comprises argon or oxygen.

4. The light-emitting diode structure of claim 1, wherein the current blocking member comprises the second semiconductor layer doped with silicon, magnesium or combination thereof.

5. The light-emitting diode structure of claim 4, wherein the current blocking member further comprises argon or oxygen

6. The light-emitting diode structure of claim 1, wherein the current blocking member comprises silicon oxide, silicon nitride, zinc oxide or any combinations thereof.

7. The light-emitting diode structure of claim 6, wherein the current blocking member is disposed within the first semiconductor layer.

8. The light-emitting diode structure of claim 6, wherein the current blocking member is disposed within the first semiconductor layer and the light-emitting layer.

9. The light-emitting diode structure of claim 6, wherein the current blocking member is disposed within the first semiconductor layer, the light-emitting layer and the second semiconductor layer.

10. The light-emitting diode structure of claim 1, wherein the first contact electrode is at least 5μm distant from the second contact electrode.

11. A manufacturing method for a light-emitting diode structure comprising:
providing a first substrate having a first semiconductor layer formed thereon;
forming a first opening on the first semiconductor layer;
forming a lump member within the first opening;
sequentially forming a light-emitting layer and a second semiconductor layer on the first semiconductor layer, wherein the first and second semiconductor layers are of opposite conductivity types;
forming a current blocking member, wherein forming the current blocking member comprises removing at least a portion of the lump member to form a second opening exposing the first semiconductor layer, and wherein the second opening is surrounded by the current blocking member;
forming a first contact electrode on an upper surface of the second semiconductor layer;
conformally forming a barrier layer over the first contact electrode and the second opening;
forming a second contact electrode over the first contact electrode and the second opening; and
forming a second substrate over the second contact electrode and removing the first substrate.

12. The method of claim 11, wherein forming the current blocking member further comprises:
executing an implanting process to dope silicon and magnesium into the first semiconductor layer.

13. The method of claim 12, wherein forming the current blocking member further comprises:
using the lump member as a mask to dope the first semiconductor layer before the second opening is formed; and
removing the lump member after the light-emitting layer and the second semiconductor layer are formed.

14. The method of claim 12, wherein forming the current blocking member further comprises:
using the lump member as a mask to dope the first semiconductor layer, the light-emitting layer and the second semiconductor layer before the second opening is formed; and
removing the lump member after the light-emitting layer and the second semiconductor layer are formed.

15. The method of claim 12, wherein forming the current blocking member further comprises:
doping argon or oxygen into the first semiconductor layer.

16. The method of claim 12, wherein the implanting process comprises an ion bombardment method.

17. The method of claim 11, wherein forming the current blocking member further comprises:
executing an implanting process to dope silicon and magnesium into the second semiconductor layer.

18. The method of claim 17, wherein forming the current blocking member further comprising:
using the lump member as a mask to dope the second semiconductor layer after the light-emitting layer and the second semiconductor layer are formed; and
removing the lump member to form the second opening.

19. The method of claim 17, wherein forming the current blocking member further comprising:
doping argon or oxygen into the second semiconductor layer.

20. The method of claim 11, wherein the current blocking member comprises silicon oxide, silicon nitride, zinc oxide or any combinations thereof.

21. The method of claim 20, wherein forming the current blocking member further comprises:
forming a third opening around the lump member by a photolithography and etching process before the second opening is formed; and
forming the current blocking member within the third opening.

22. The method of claim 20, wherein forming the current blocking member further comprises:
removing a portion of the lump member to enable the remaining portion of the lump member to form the current blocking member.

23. The method of claim 11, wherein a top surface of the lump member is higher than or aligned with a top surface of the first semiconductor layer.

24. The method of claim 11, wherein a top surface of the lump member is lower than a top surface of the second semiconductor layer.

25. The method of claim 24, wherein the light-emitting layer and the second semiconductor layer are formed not to cover the top surface of the lump member.

26. The method of claim 11, wherein the first contact electrode is at least 5 μm distant from the second contact electrode.
